(19) United States
(12) Patent Application Publication
(10) Pub. No.: US 2012/0186747 A1
(43) Pub. Date: Jul. 26, 2012

(54) PLASMA PROCESSING APPARATUS

(76) Inventors: Shinji OBAMA, Kudamatsu (JP); Masaru Izawa, Hino (JP); Kenji Maeda, Kodaira (JP); Yoshihide Kihara, Sendai (JP); Kouichi Yamamoto, Hikari (JP); Hitoshi Tamura, Hikari (JP)

(21) Appl. No.: 13/236,775

(22) Filed: Sep. 20, 2011

(30) Foreign Application Priority Data
Jan. 26, 2011 (JP) 2011-013559
Feb. 25, 2011 (JP) 2011-039183

(51) Int. Cl. H01L 21/00; C23F 1/08

(52) U.S. Cl. 156/345.42; 156/345.51

(57) ABSTRACT

A plasma processing apparatus is provided with a processing chamber which is arranged inside a vacuum container and plasma is formed inside, a circular shape plate member made of a dielectric material arranged above the processing chamber through which an electric field is transmitted, and a cavity part having a cylindrical shape arranged above the plate member and the electric field is introduced inside, in which the cavity part is provided with a first cylindrical cavity part having a cylindrical shape cavity with a large diameter and having the plate member as the bottom face, a second cylindrical cavity part arranged above to be connected to the first cylindrical cavity part and having a cylindrical shape cavity with a small diameter, and a step portion for connecting these between the first and the second cylindrical cavity parts.

### BACKGROUND OF THE INVENTION

The present invention relates to a plasma processing apparatus and a plasma processing method using a microwave with a magnetic field, and more specifically the present invention relates to a plasma processing apparatus suitable for etching processing of a laminated film on a wafer surface in a manufacturing process of a semiconductor device.

According to the International Technology Roadmap for Semiconductor (ITRS), mass production of a node with a MPU physical gate length of 22 nm would be started in 2012, which requires to secure performance of an allowable gate length difference (CDU) of wafer in-plane<1.0 nm. Further, it is expected that a line for processing a wafer of 450 mm will start up in 2015. Accompanying with this, the next generation plasma processing apparatus in response to a finer semiconductor device and a larger diameter wafer is required, and in particular, development of a plasma source having high uniformity over a wide area for the above wafer diameter of 450 mm (18 inch) has become an urgent need.

In a manufacturing process of a semiconductor device, plasma processing such as plasma etching and plasma CVD has widely been used. Plasma is generated by providing radio frequency power or microwave power in a vacuum processing chamber to excite gas particles supplied inside. In the above plasma processing, a substrate-like sample such as a semiconductor wafer arranged in the vacuum processing chamber is processed using this plasma.

That is, a desired profile is obtained by attracting charged particles such as ions in this plasma onto the wafer surface, promoting a chemical reaction between radicals (activated particles) having high reactivity formed by plasma and a film-like material arranged on the wafer surface, and making a process of the relevant film to proceed. For such plasma processing, profile controllability and process uniformity in the wafer plane in a pressure region corresponding to minitualization of semiconductor devices have been required.

Namely, in the plasma processing apparatus for etching processing or the like of the semiconductor wafer as described above, it is required to perform uniform processing at the whole surface of a substrate such as the semiconductor wafer, which is an object to be processed. To attain this, it is preferable that plasma formed above the sample has uniform characteristics of density, intensity or the like in a surface direction (a radial direction and a circumferencial direction) of the sample, and thus generation of such uniform plasma has been required. As uniform characteristics, various plasma parameters, specifically, electron density, electron temperature, space potential or the like can be listed.

For such a problem, it has been considered conventionally the one provided with a configuration in which a cavity part is arranged over a processing chamber and an electric field introduced into the processing chamber is introduced into the processing chamber after acquiring specific characteristics once in the cavity part thereof. That is, it has been considered to try for solving the above problem by making distribution of an electric field with which non-uniformity of the above parameters of plasma formed inside the processing chamber can be suppressed in such a cavity part.

In particular, a microwave plasma etching apparatus with a magnetic field, which forms plasma by generating ECR (Electron Cyclotron Resonance) using a microwave of 2.45 GHz and a solenoid coil magnetic field (875 Gauss), has been used in the manufacturing process of a semiconductor because it can generate high density plasma under low pressure.

As an example of such conventional technology, the one disclosed in JP-A-7-235394 has been known. In this conventional technology, the microwave of 2.45 GHz is introduced into a cylindrical cavity by propagating it through a rectangular waveguide and a circular waveguide. At this time, the microwave is propagated through the rectangular waveguide in the TE01 mode and through the cylindrical waveguide in the TE11 mode. Microwave entering inside the cylindrical cavity in this mode is introduced into a vacuum processing chamber via a microwave transmitting window and a shower plate. Then, a magnetic field is formed in an axial direction in the processing chamber with a solenoid coil surrounding the vacuum processing chamber to form an equi-magnetic field plane of 875 Gauss in a radial direction. ECR is generated by an electric field of 2.45 GHz and a magnetic field of 875 Gauss to generate plasma in the vacuum processing chamber. Specifically, because electrons receive Lorentz force from the magnetic field and the microwave becomes cyclotron frequency, electrons feel an electric field of the same phase and are accelerated in a direct current manner in response to electric power. Therefore, high-speed electrons promote ionization and form high density plasma even under low pressure.

Inside the cylindrical cavity part of the microwave plasma etching apparatus, a microwave of the TE11 mode, which has passed through a cylindrical waveguide, forms a standing wave having reflection ends at plural places of the processing chamber in the cylindrical cavity part. As the reflection ends, any places such as the microwave transmitting window made of quartz, the shower plate made of quartz, plasma, electrodes in the processing chamber transmitted through the plasma (a sample stage), and the lower end of the processing chamber become end points. Additionally, it has been known that, because quartz is dielectric, reflection is repeated in the microwave transmitting window, in the shower plate, between the lower face of the microwave transmitting window and the upper face of the shower plate, so that they become reflection ends.

Also, in the case where plasma density is over a certain level (electron density>1×10¹¹ cm⁻³, in the case with a magnetic field), the O-wave component of the microwave becomes a cut-off and the microwave shows total reflection by plasma. From these reflection ends and the incident end of the circular waveguide, travelling waves and reflected waves interfere complicatedly, and thus standing waves having various modes, that is, various wavelengths are generated in the cylindrical cavity. These standing waves having a single mode of the incident wave TE1 or plural modes in the cylindrical cavity part pass through the microwave transmitting window, enter the vacuum container, and act as an ignition source of plasma, which determines uniformity of plasma, and thus uniform and stable high density plasma has been generated by suitably selecting a height of the cylindrical cavity conventionally.

In addition, as another conventional technology, as described in JP-A-7-335631, there has been known the one generating uniform plasma by providing a cavity part between a processing chamber for generating plasma and a waveguide for introducing a microwave and by forming a standing wave associated with a specific electric field mode in the cavity part. In this conventional technology, it has been disclosed that, because the TE11 mode microwave directly introduced from the waveguide contributes into increase of plasma density at the center part while a standing wave of the TE01 mode is excited between a plasma interface and the cavity part by providing a cavity part with nearly the same diameter as that of a plasma formation part and by adjusting the cavity height optimally to increase plasma density at a peripheral part by this TE01 mode, uniform plasma is generated by superposing these.

Further, in JP-A-4-217318, there has been disclosed a technology for providing a mechanism for continuously changing a height of the cavity part and adjusting the height in response to plasma density.

### SUMMARY OF THE INVENTION

In the above conventional technology, because the TE11 mode is transmitted in the circular waveguide, the TE modes (TE11, TE21, TE01, and the like) tend to be generated in the cylindrical cavity part and fundamentally standing waves of the TE modes are generated in the cylindrical cavity part, thus it has been intended to realize uniform plasma density by propagating a nearly uniform microwave over a wide area of the vacuum processing chamber. However, according to investigation of the present inventors, such knowledge has been obtained that, since, in such technology, a plasma state of the reflection end of a standing wave changes depending on conditions such as gas species, pressure in the vacuum processing chamber, and a magnetic field profile, which are plasma generation parameters, a electric field distribution changes in the cylindrical cavity part and modes other than the TE modes are generated.

As one example of the TE mode in the cylindrical cavity part, a profile of the convex shape in the radial direction was obtained, having extremely strong electric field intensity at the center and mildly weak at the outer circumference, provided that a process rate in a TE mode becomes uniform in a wafer surface direction (so-called an in-plane direction). This is also transcribed to plasma, and in the case of an ICF (Ion Current Flux) distribution, it appears as a distribution having higher ICF current at the center and lower at the outer circumference, and in the case of a rate distribution, it appears significantly as a distribution having a high rate at the center and low at the outer circumference. In such plasma, even when the profile is in the convex type, by controlling to give temperature difference between at the center and at the outer circumference of a sample stage and changing an amount of incident ions, an in-plane uniformity of finish of the sample was attained.

Other than this control at the sample stage, it has been known experimentally that in a conventional cylindrical cavity structure, in particular, under process conditions for a fluoride system, a part directly under a circular waveguide, that is, a connection part of the circular waveguide and the upper lid of the cylindrical cavity part becomes discontinuous, extremely strong electric field is generated at this discontinuous part, and two small circular plasma (hereafter, referred to as abnormal discharge) are generated other than plasma being generated in the processing chamber. This abnormal discharge is generated directly under the shower plate made of quartz, between the microwave transmitting window made of quartz and the shower plate, or the like. Therefore, there was the case of appearing a transcribed shape as an in-plane distribution of etching rate on a wafer, taking an M-type or a W-type profile in the radial direction. Therefore, there was the case of evident lack of uniformity of rate distributions on the wafer, in the circumference direction and the radial direction, respectively, depending on process conditions.

Therefore, a profile of plasma generated inside the processing chamber can be adjusted by temperature difference of the wafer sample stage, in the case of a state that it is uniform in the circumference direction and has a small gradient difference between the center and the outer circumference in the radial direction such as being convex or concave. However, it is considered that this variation difference increases further in a large diameter of 450 mm because it depends largely on plasma.

Furthermore, in JP-A-7-335631, there may be the case where an effect of the TE01 mode microwave, which enhances plasma density at the circumference part, becomes insufficient depending on processing conditions and thus there was no consideration on the point that plasma characteristics become non-uniform in response to processing conditions.

That is, there is the case where plasma density becomes relatively high at the center part due to an influence by the microwave of the TE11 mode. There is no consideration on a problem that, especially in the case where processing pressure becomes relatively high, even when by superposing electric fields of the TE01 mode and the TE11 mode like in the conventional technology, plasma density decreases at the circumference part, and as a result, uniformity of characteristics such as plasma density can not be attained.

In addition, there is no consideration on a point that, when the sample diameter becomes large and the size of the processing chamber is enlarged accordingly, the density of plasma formed in the processing chamber becomes lower at the circumference part, which impairs the uniformity of plasma.

Further, in JP-A-4-217318, only a point of improving plasma density by adjusting height up to the upper end of the cavity part, which has the same value in the radial direction of a sample, in the vertical direction is taken into consideration and there is no consideration on an aspect of adjusting the height of the cavity part, which is necessary in suppressing plasma non-uniformity in the radial or circumference direction.

It is an objective of the present invention to provide a plasma processing apparatus having an improved uniformity in processing characteristics or machined profiles in the radial direction of the sample.

The above objective is attained by a plasma processing apparatus in which the upper face of the cavity part is divided in two or more concentrically and the center side and the circumference side have different cavity heights. Further, it is attained by a plasma processing apparatus having a device which enables to separately adjust a height of each of the center side and the circumference side of the upper surface of the cavity part and by a processing method using the same.

In more detail, the above objective is attained by a plasma processing apparatus including a vacuum container; a processing chamber which is arranged inside this vacuum container and inside which plasma is formed; a sample stage which is arranged inside this processing chamber and on an upper face of which a sample is mounted; a circular shape plate member made of a dielectric material which is arranged above the processing chamber and through which an electric field supplied to form the plasma is transmitted; a cavity part having a cylindrical shape which is arranged above this plate member and inside which the electric field is introduced; a cylindrical-shape conduit the inside of which is coupled to the center of the upper part of this cavity and extends in the vertical direction through which the electric field is propagated; and a generator arranged at an end part of this conduit for generating the electric field; wherein the cavity part is provided with: a first cylindrical cavity part having a cylindrical-shape cavity with a large diameter and having the plate member as the bottom face; a second cylindrical cavity part arranged to be connected to this first cylindrical cavity part above and having a cylindrical-shape cavity with a small diameter; and a step portion for connecting these between the first and the second cylindrical cavity parts.

Further, it is attained by including another step portion which connects the second cylindrical cavity part and the conduit therebetween and providing a ceiling face of the cavity part with a plane in parallel to the plate member.

Furthermore, it is attained by arranging a ceiling face of the second cylindrical cavity part in parallel to the plate member and setting a height H2 of this ceiling face from the upper face of the plate member in a range of λ<H2<5λ/4 with respect to a wavelength λ of the electric field.

Furthermore, it is attained by arranging a ceiling face of the first cylindrical cavity part in parallel to the plate member and setting a height H1 of this ceiling face from the upper face of the plate member in a range of λ/4<H1 with respect to a wavelength λ of the electric field.

Furthermore, it is attained by setting a radius R2 of a cylindrical shape of the second cylindrical cavity part in a range of λ/4<R2 with respect to a wavelength λ of the electric field.

Furthermore, it is attained by arranging the second cylindrical cavity part so that the center thereof matches to the center axis of the sample stage having a cylindrical shape and arranging the step portion more toward the center side than the outer circumference of the sample stage having a cylindrical shape with regard to a direction from the center axis toward the outer circumference.

Furthermore, it is attained by the electric field which is an electric field of a microwave of 2.45 GHz, and by providing with a magnetic field generation device for supplying a magnetic field of 875 Gauss inside the processing chamber to form the plasma by ECR inside the processing chamber.

Furthermore, it is attained by supplying the microwave of the TE11 mode from the conduit to the cavity part.

In addition, it is attained by a plasma processing apparatus including a cylindrical-shape processing chamber which is arranged inside a vacuum container and inside which plasma is formed; a sample stage which is arranged inside this processing chamber and on which a sample to be processed by the plasma is arranged; a disc member made of a dielectric material arranged at the upper part of the vacuum container and through which an electric field to form the plasma in the processing chamber is transmitted; a cavity having a cylindrical shape which is arranged above this disc member and in which the electric field is introduced from above; a waveguide which is coupled thereto and arranged above the center of this cavity and through the inside of which the electric field is propagated; a device arranged at an end part of this waveguide for generating the electric field; a first and a second cavity parts having different heights from the upper face of the disc member at the center part constituting the cavity and including the coupling part with the waveguide and the outer circumference part of this center part; an adjuster arranged above these first and second cavity parts to adjust these heights; and a controller for transmitting a command to change heights of the first and the second cavity parts to the adjuster with progress of the processing.

Also, it is attained by providing the first cavity part with a first ring-like plate member which is arranged at the outer circumference of the waveguide to constitute the ceiling of this cavity part and moves vertically; and providing the second cavity part with a second ring-like plate member which is arranged at the first ring-like outer circumference side to constitute the ceiling of this cavity part and moves vertically; and a cylindrical member which constitutes the side wall of the first cavity part between a step between the first ring-like plate member and the second ring-like plate member.

Furthermore, it is attained by arranging the upper face of the sample stage on which the sample is mounted under the coupling part of the waveguide and the cavity and by positioning the step more toward the center side than the outer circumference edge of the sample stage as being viewed from above.

Furthermore, it is attained by setting a distance between the first ring-like plate member and the disc member larger than a distance between the second ring-like plate member and the disc member.

Furthermore, it is attained by adjusting a ratio of the distances between the first and the second ring-like plate members and the disc member in over-etching processing of a film arranged on the top surface of the sample to be smaller than a ratio of these distances in main etching of the film.

Furthermore, it is attained by adjusting a ratio of the distances of the first and the second ring-like plate members and the disc member in a step of processing at a high pressure in the processing chamber to be smaller than a ratio of these distances in a step of processing at a low pressure.

Other objects, features, and advantages of the invention will become apparent from the following description of the embodiments of the invention taken in conjunction with the accompanying drawings.

### BRIEF DESCRIPTION OF THE DRAWINGS

FIG. 1 is a longitudinal cross-sectional view showing a schematic configuration of a plasma processing apparatus according to an embodiment of the present invention;

FIG. 2 is a longitudinal cross-sectional view enlarged to show an electric field introducing part arranged at the upper part of the plasma processing apparatus according to the embodiment shown in FIG. 1;

FIG. 3A and FIG. 3B are schematic diagrams showing distributions of an electric field and a magnetic field in a cross-section cut in a horizontal direction inside a cylindrical cavity part in a conventional technology;

FIG. 4A and FIG. 4B are schematic diagrams showing distributions of an electric field and a magnetic field in a cross-section cut in a horizontal direction inside a cylindrical cavity part in the present embodiment shown in FIG. 1;

FIG. 5 is a longitudinal cross-sectional view schematically showing an electric field in a cylindrical cavity part in the present embodiment shown in FIG. 1;

FIG. 6 is a graph showing distributions of ion currents (ICF distributions) in an in-plane direction of a sample from plasma in the processing chamber to an electrode in a sample stage of a conventional technology and the present embodiment shown in FIG. 1;

FIG. 7 is a longitudinal cross-sectional view describing a schematic configuration of a plasma processing apparatus according to another embodiment of the present invention;

FIG. 8A and FIG. 8B are schematic diagrams showing examples of film structures arranged at the top surface of a wafer to be processed with the plasma processing apparatus according to the embodiment shown in FIG. 7;

FIG. 9 is a flowchart showing a flow of an operation when the film structures shown in FIG. 8A and FIG. 8B are processed with the plasma processing apparatus according to the embodiment shown in FIG. 7;

FIG. 10 is a longitudinal cross-sectional view showing a schematic configuration of a modified embodiment of the plasma processing apparatus according to the embodiment shown in FIG. 7;

FIG. 11A and FIG. 11B are schematic diagrams showing other examples of film structures arranged at the top surface of a wafer to be processed with the plasma processing apparatus according to the embodiment of the present invention shown in FIG. 8A and FIG. 8B; and

FIG. 12 is a flowchart showing a flow of an operation when the plasma apparatus according to the embodiment shown in FIG. 7 or FIG. 10 performs etching processing of the film structures shown in FIG. 11A and FIG. 11B.

### DESCRIPTION OF THE EMBODIMENTS

In an embodiment of a plasma processing apparatus according to the present invention to be explained below, the objective to solve the above problem is attained by making a cylindrical cavity part comprising a cylindrical shape cavity of plural stages so that plural cylindrical shape parts having a first and a second cylindrical cavity parts with different diameters are coupled concentrically in the vertical direction. In a plasma processing apparatus according to an embodiment of the present invention to be explained below in detail, a waveguide and a cavity resonance part, which are compositions arranged at the upper part thereof for propagating an electric field, contain a cylindrical shape cavity inside the upper face of which has plural steps at the upper part thereof and an electric field of a microwave introduced into the inside thereof is made to resonate and to have distributions of propagation in a desired manner so as to suppress non-uniformity of distribution of a electric field to be introduced by being propagated into a processing chamber down below and to enhance uniformity thereof.

In the present embodiment, a microwave which is propagated in the TE11 mode through a circular waveguide is converted to the TM12 mode at the cylindrical cavity part. In this way, more intense plasma compared with a conventional one is formed at an intermediate position between the center and the wall face of the vacuum processing chamber. In this way, non-uniformity of the distribution of plasma density or intensity is reduced and processing of improved uniformity can be performed.

Explanation is given below on embodiments of the present invention with reference to the drawings.

### Embodiment 1

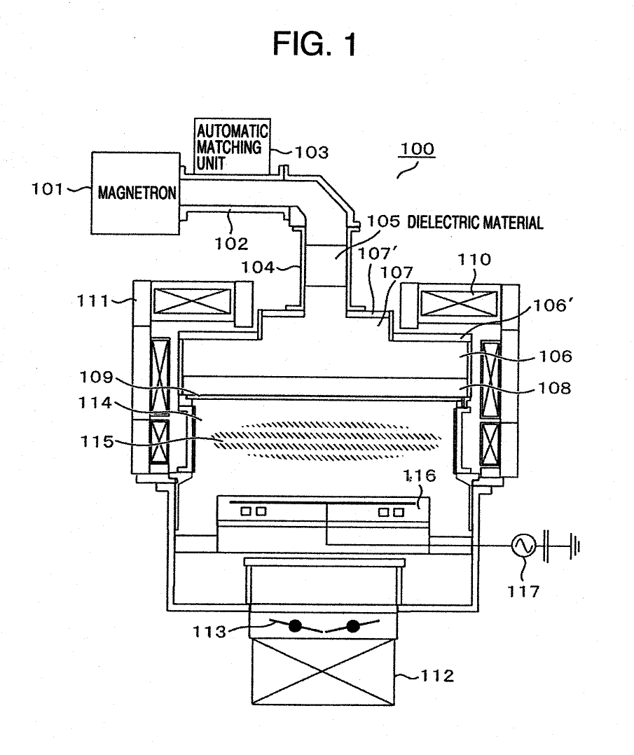

FIG. 1 is a longitudinal cross-sectional view showing a schematic configuration of a plasma processing apparatus according to an embodiment of the present invention. In the present figure, a plasma processing apparatus 100 according to the present embodiment comprises a vacuum container provided inside with a processing chamber 114 having a cylindrical shape; an electric field introducing part arranged at the upper part thereof for generating and propagating an electric field introduced into the processing chamber 114; and an exhaust part arranged underneath the vacuum container for expelling gas, products, and plasma particles inside the processing chamber 114 to the outside of the vacuum container to exhaust the inside of the processing chamber 114.

The electric field introducing part comprises, by rough classification, a magnetron 101, which is a forming device of an electric field of a microwave with a frequency of 2.45 GHz; a waveguide at an end of which this is arranged and made as coupled conduits each of which has a cross-sectional shape of a rectangle or a circle; and a resonance part having a chamber space of a cylindrical shape which is coupled at the lower end part of the waveguide and arranged above the processing chamber 114 to cover this; these are coupled and arranged in the order explained above. The microwave with a frequency of 2.45 GHz, excited and formed by the magnetron 101 arranged at the end part (a left end part in the figure) of the waveguide part, is propagated inside a rectangular waveguide 102 which composes the waveguide part and at the side face of one end part of which the magnetron 101 is installed.

The waveguide part comprises a rectangular waveguide 102 with a rectangular cross-section, which is arranged at the upper part extending in a horizontal direction in the figure and at one end part of which a forming device of the electric field is coupled and arranged; and a circular waveguide 104 with a circular shape cross-section, which is coupled to this rectangular waveguide 102 under the other end part thereof extending in the vertical direction. Inside the rectangular waveguide 102 and the circular waveguide 104, the electric field of the microwave has a specific mode as a dominant distribution of its intensity or density and is propagated toward the end part of the waveguide part. Incidentally, the present embodiment has a directional coupler and an automatic matching unit 103 at the upper face between one end part and the other end part of the rectangular waveguide 102.

In the present embodiment, the electric field of the microwave having the TE01 mode is propagated inside the rectangular waveguide 102 toward the right end part in the figure. The electric field reaching the right end part of the rectangular waveguide 102 is introduced into the circular waveguide 104 coupled and arranged underneath via a conversion waveguide. The electric field is propagated inside the circular waveguide 104 with the TE11 mode as a dominant distribution toward the lower end part down in the figure.

The circular waveguide 104 comprises a dielectric material 105 made of quartz or the like inside the tube of a circular shape cross-section for circularly polarized wave mode conversion of the electric field. The dielectric material 105 has a cylindrical shape and is arranged densely in contact with the inner wall face inside the tube. By inserting this dielectric material 105 to a position in a 45 degree direction relative to a composite electric field vector of the TE11 mode, the introduced TE11 mode electric field can be converted to a circularly polarized wave rotated in the circumference direction at the exit because its phase is delayed by 90 degrees.

By the electric field rotating in the circumferential direction at a circular shape cross-section of this circular waveguide 104, the electric field becomes improved in uniformity as non-uniformity of a distribution of its strength or density is suppressed in time. Uniformity of the intensity or density distribution of the plasma formed in the processing chamber by introducing such an electric field below is improved similarly.

The electric field, reaching the end part of the circular waveguide 104 as rotating in the circumferential direction of the cross-section and having the TE11 mode as a predetermined mode, is introduced into the cylindrical cavity part coupled to the lower end part thereunder. The cylindrical cavity part of the present embodiment contains an internal cavity in which cylindrical shapes having two different diameters as described above are coupled vertically and concentrically, and a diameter of a second cylindrical cavity part 107 arranged above is set smaller than a diameter of a first cylindrical cavity part 106, which is the cylindrical cavity part below.

In the present embodiment, the first cylindrical cavity part has the same diameter as that of the processing chamber 114 arranged below with a concentric cylindrical shape. The lower end part of the circular waveguide 104 is connected along an inner circumferential edge of a circular shape opening, which is arranged at the center part of a ring-like disc 107′ composing the upper face of the second cylindrical cavity part 107 arranged above the first cylindrical cavity part 106, and the inside of the second cylindrical cavity part 107 and the inside of the circular waveguide 104 are communicated by communicating the circular shape opening and the inside of the circular waveguide 104.

Further, the upper part of the first cylindrical cavity part 106 is a ring-like planar disc at the center part of which there is a circular shape space and has a first upper face plate 106′ the lower face of which constitutes a ceiling face of the cylindrical shape space in the first cylindrical cavity part 106. The circular shape opening at the center part of the first upper face plate 106′ faces inside of the second cylindrical cavity part 107 coupled above and is communicated to the first cylindrical cavity part 106 and the second cylindrical cavity part 107 are communicated with each other by the insides thereof by the circular shape opening at the center part of the first upper face plate 106′.

The electric field of the microwave which is a circularly polarized wave introduced into the cylindrical cavity part by being introduced into the second cylindrical cavity part 107 becomes one having a predetermined intensity or density distribution and a propagation mode inside the cylindrical cavity part and is introduced into the processing chamber 114 after being transmitted through a microwave introducing window 108, which is a disc made of a dielectric material such as quartz, constitutes the bottom face of the first cylindrical cavity part 106, and is arranged concentrically thereto, and a shower plate 109, which is a disc made of a dielectric material such as quartz, is arranged below the microwave introducing window, constitutes the ceiling face of the processing chamber 114 facing the inside thereof.

Incidentally, the electric field introducing part has one to three systems of solenoid coils 110 and a yoke 111 which are arranged at the outer circumference of the side walls of the vacuum container constituting the processing chamber 114 and the cylindrical cavity part and above the upper face by surrounding these. They form a static magnetic field in its axial direction inside the processing chamber 114 by direct current power supplied.

The microwave introducing window 108 has a sealing device such as O-ring to air-tightly seal between the inside and the outside of the processing chamber 114 therebelow at the outer circumference edge part thereof. By this sealing device, the inside and the outside of the processing chamber 114, which is evacuated and made to a predetermined degree of vacuum during processing, are sealed so as to maintain an expected pressure difference.

Under the microwave introducing window 108 a disc-like shower plate 109 is arranged with a predetermined gap between them. Plural through holes are arranged in a predetermined range at the center of the shower plate 109 and process gas is introduced into the processing chamber 114 through them. The process gas passes through a supply conduit coupled to a gas source, which is not shown, is introduced into a gap between the microwave introducing window 108 and the shower plate 109, diffuses inside the gap, and flows in from the plural through holes communicated to the gap to the inside of the processing chamber 114 from above so that non-uniformity of a distribution of the process gas inside the processing chamber 114 is reduced.

Below the shower plate 109 inside the processing chamber 114 a sample stage 116 is arranged, which has a cylindrical shape and comprises a disc-like electrode made of a conductor inside and on which a semiconductor wafer as a sample is mounted. The sample stage 116 is arranged with a gap with the side wall of the processing chamber 114 having a cylindrical shape and is connected with the side wall by plural support beams in a horizontal direction (a left and right direction in the figure). The sample stage 116 is held in the processing chamber 114 inside the vacuum container by these support beams with an open space under the sample stage 116, so to speak, in the air.

Under the vacuum container, an exhaust part is arranged to adjust the inside to a predetermined pressure during processing or the like by evacuating the inside of the processing chamber 114. At the lower part of the processing chamber 114 directly below the sample stage 116, an opening is arranged through which the process gas introduced into the processing chamber 114 and products, plasma particles, and the like formed during processing flow out; the particles are exhausted from this opening through a flow passage.

In the plasma processing apparatus 100 according to the present embodiment, comprising the exhaust part under the opening, there are arranged a variable valve 113 having plural plate-like flaps for increasing or decreasing the cross-sectional area of the flow passage by rotating around the rotating axis arranged to intersect the axial direction of the flow passage and a turbo-molecular pump 112 which is a vacuum pump an inlet of which is communicated to an exit of the flow passage thereunder. By adjusting operation of the turbo-molecular pump 112 and a rotation action of the variable valve 113 as well as introduction mass rate of the process gas introduced from a gas source through the gap and the introducing holes, pressure inside the processing chamber 114 is adjusted to a predetermined degree of vacuum.

In the side wall of its vacuum container, the plasma processing apparatus 100 is coupled to a transfer container, which is another not-shown vacuum container configuring a transfer chamber depressurized to the equivalent degree of vacuum to that in the processing chamber 114 and the processing chamber 114 within and the transfer chamber are opened or blocked with an open-close valve such as a gate valve, which is not shown. A sample, which is transferred in the transfer chamber being mounted on a transfer device such as a robot arm, which is not shown, in a state of reduced pressure to a predetermined degree of vacuum by introducing gas such as argon in the processing chamber 114, is delivered to the sample stage 116 above the mounting surface constituting the top surface of the sample stage 116 in the processing chamber 114 while the gate valve is open.

After closing the above gate valve to air-tightly seal the inside of the processing chamber 114 from the outside, the sample is mounted on the mounting surface of the sample stage 116 and adhered and retained using a electrostatic chuck device which is not shown; heat transfer gas is supplied to a gap between the rear side surface of the sample and the mounting surface from an introducing port arranged on the mounting surface for promoting heat transfer between them.

The process gas is introduced into the processing chamber 114 from plural introducing holes arranged within a region of a predetermined radius of the center part of the shower plate 109, which is arranged above the mounting surface of the sample stage 116 in parallel thereto. Furthermore, the inside of the processing chamber 114 is evacuated by operations of the turbo-molecular pump 112 and the variable valve 113 of the exhaust part through the opening arranged directly under the processing chamber 114 to be decompressed so that the inside of the processing chamber 114 is adjusted to pressure of a predetermined degree of vacuum in a range of 0.05 to 5 Pa by balance of these.

In this state, an electric field of 2.45 GHz is introduced into the processing chamber 114 from above being transmitted through the microwave introducing window 108 and the shower plate 109 and at the same time a static magnetic field of an intensity of 875 Gauss formed by the solenoid coil 110 to generate an ECR with an electric field of 2.45 GHz is introduced. By the ECR generated as an interaction of this electric field and the magnetic field, the process gas is excited to form plasma 115 inside the processing chamber 114.

Once the plasma 115 is formed, radio frequency power of 400 kHz to 13.56 MHz is applied to an electrode constituted by an electrically conductive member not shown and arranged inside the sample stage 116 on which a sample is mounted from a radio frequency power supply 117 electrically connected thereto, in one or two systems. By this supplied radio frequency power, a bias potential is formed above the mounting surface of the sample stage 116 or the top surface of the sample and charged particles such as ions in the plasma 115 are attracted to the sample surface by a potential difference between a potential of the plasma 115 and a bias potential, resulting in collision onto a film of a processing object on the sample surface. Using the incident energy on this collision a reaction between highly active particles generating in the plasma 115 and a material composing the film is enhanced to perform etching of a film structure containing the above film to a desired profile.

When it is detected that the etching processing has been performed to a desired profile or processing of the film of the processing object has reached an end point, supply of the radio frequency power is stopped to extinguish the plasma 115. Then, along with stopping the supply of the heat transfer gas introduced to the rear surface of the sample, adhesion and retention of the sample on the mounting surface using the electrostatic force are released to make the sample freed and detached from the mounting surface onto the sample stage 116.

After then, the gate valve is opened to transfer out the sample by a robot arm to the inside of the transfer chamber which is outside the processing chamber 114 or the vacuum container. Next, when a sample to be processed in the processing chamber 114 is present, this sample is transferred in the processing chamber 114 again by the robot arm, mounted on the sample stage 116, and processed similarly as above.

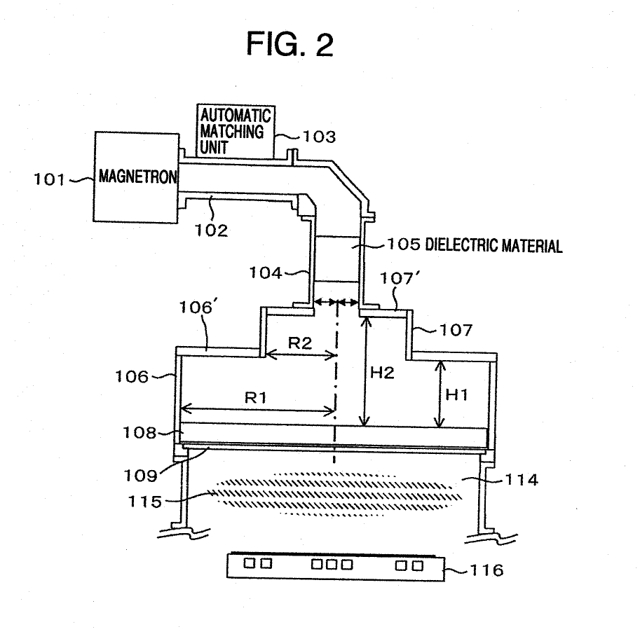

Operations of each part of the plasma processing apparatus 100 in processing the sample described above are adjusted by a control part which is not shown. Each part has a detecting device such as a sensor for detecting states of the operations and the detection device and the control part are connected by a communication device in a communication capable way. The control part comprises a calculator for judging a state thereof based on a received signal from the detection device or calculating a command signal to each part, a memory device such as a semiconductor memory or a hard disc drive for memorizing a state based on the received signal or for memorizing a program to calculate judgment or commands, and an interface for exchanging the command signals from the calculator or the signal output from the detection device with the communication device; based on the command signals from the calculator, the operations of each part are performed in suitable timings and by suitable amounts. Explanation is given on propagation of the electric field in the cylindrical cavity part of the present embodiment with reference to FIG. 2. FIG. 2 is a longitudinal cross-sectional view enlarged to show the electric field introducing part arranged at the upper part of the plasma processing apparatus according to the embodiment shown in FIG. 1. In the present figure, a discharge part which constitutes the processing chamber 114 and in which the plasma 115 is generated in a space of the cylindrical shape and a side wall part of the cylindrical shape of the vacuum container surrounding this are shown underneath the microwave introducing window 108; the part below the vacuum container is omitted in illustration. In addition, as for parts referred to with the same reference signs as in FIG. 1, explanation is omitted when explanation is not particularly need.

In the present embodiment, when the electric field of the microwave which is propagated inside the circular waveguide 104 reaches the lower end part of the circular waveguide 104, it is introduced into the cylindrical cavity part which comprises a cavity inside with a cylindrical shape and having a larger radius than that of the circular waveguide 104 coupled thereto. The cylindrical cavity of the present embodiment comprises the first cylindrical cavity part 106 of the larger radius having a radius R1 which has a size of the same or similar to presumably the same as that from the center of the processing chamber 114 having a cylindrical shape inside thereof to the inside wall surface; and the second cylindrical cavity part 107 of the smaller radius which is coupled and arranged above this first cylindrical cavity part 106 concentrically thereto and has a radius R2 which is smaller than the radius R1.

Further, the upper part of the second cylindrical cavity part 107 has a second upper face plate 107′ which is a ring-like planar disc with a circular shape space at the center part and the lower face thereof constitutes a ceiling face of the cylindrical shape space inside the second cylindrical cavity part 107. A circular shape opening of the center part of the second upper face plate 107′ faces the inside of the circular waveguide 104 coupled above and the second cylindrical cavity part 107 and the circular waveguide 104 are communicated inside by the circular shape opening. Furthermore, in the present embodiment, the radius of the inner circumferential edge of the circular shape opening has a size of the same value or similar to presumably be the same as the inner radius of the circular waveguide 104 and the inner circumferential end of the circular opening of the second upper face plate 107′ is connected to the lower end part having the circular shape opening of the circular waveguide 104 and a flange of the outer circumference side thereof.

Further, the upper part of the first cylindrical cavity part 106 has the first upper face plate 106′ which is a ring-like planar disc with a circular shape space at the center part and the lower face thereof constitutes a ceiling face of the cylindrical shape space inside the first cylindrical cavity part 106. A circular shape opening of the center part of the first upper face plate 106′ faces the inside of the second cylindrical cavity part 107 coupled above and the first cylindrical cavity part 106 and the second cylindrical cavity part 107 are communicated inside by the circular shape opening of the center part of the first upper face plate 106′.

Furthermore, in the present embodiment, the radius of the inner circumferential edge of the circular shape opening has a size of the same value or similar to presumably be the same as the radius of the second cylindrical cavity part 107 or the cylindrical shape space inside thereof and the inner circumferential end of the circular opening of the first upper face plate 106′ is connected to the lower end part having the circular shape of the side wall having a cylindrical shape of the second cylindrical cavity part 107. Each of the first cylindrical cavity part 106 and the second cylindrical cavity part 107 of the present embodiment is positioned concentrically with the axis in the vertical direction of the circular waveguide 104, the microwave introducing window 108 below, and the processing chamber 114 having a cylindrical shape and they are arranged concentrically. The side walls constituting the respective cylinders of the first cylindrical cavity part 106 and the second cylindrical cavity part 107 are arranged in parallel relative to the axis described above and are connected nearly perpendicular to the lower end of the side wall of the second cylindrical cavity part 107 and the first upper face plate 106′ while the first cylindrical cavity part 106 and the second cylindrical cavity part 107 configure a step; the whole cylindrical cavity part comprises cylindrical shapes of plural stages (two stages).

The electric field of the microwave, which proceeds into the cylindrical cavity having such a configuration, diffuses inside the second cylindrical cavity part 107 with the small diameter (primary diffusion). The diffused electric field disperses and proceeds uniformly in all directions with the inner circumferential edge of the circular shape opening of the second upper face plate 107′ or the circular shape lower end part of the circular waveguide 104 as a starting point. Then, the electric field which proceeds toward the outer circumference side of the circular shape opening reflects at the inner side wall face of the second cylindrical cavity part 107 and interferes with the electric field still diffusing toward the outer circumference side so that a standing wave is generated as a steady state.

Such the electric field formed in the second cylindrical cavity part 107 is also propagated down and is introduced also into the first cylindrical cavity part 106. As a result, similar to an action at a connection part of the second cylindrical cavity part 107 and the circular waveguide 104, the electric field disperses and proceeds equally in all directions to diffuse (secondary diffusion) with the inner circumferential edge of the circular shape opening of the center part of the first upper face plate 106′ as a starting point. Then, it reflects at the inner side wall face of the first cylindrical cavity part 106 and interferes with the following electric field so that a standing wave is generated as a steady state.

The two standing waves of the electric field of the microwave generated inside two cylindrical shape spaces above and below are propagated down in the cylindrical cavity part, passes through the microwave introducing window 108 and the shower plate 109, enters inside the processing chamber 114, excites the process gas introduced into the processing chamber 114, and forms plasma 115. As for the aforementioned standing waves in the cylindrical cavity part, compositions of the processing chamber 114 such as the microwave introducing window 108 and the shower plate 109, moreover the plasma 115 and the upper face of the sample stage 116 become reflection ends as a whole and complex standing waves are formed at the microwave introducing window 108 and inside the cylindrical cavity part to become a steady state.

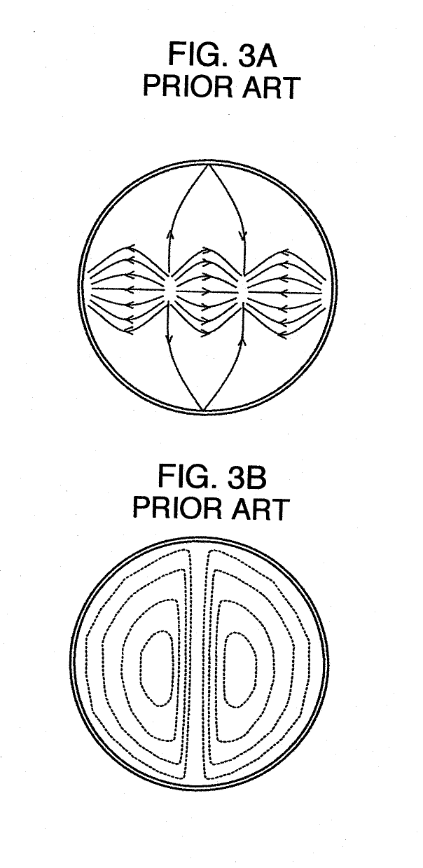

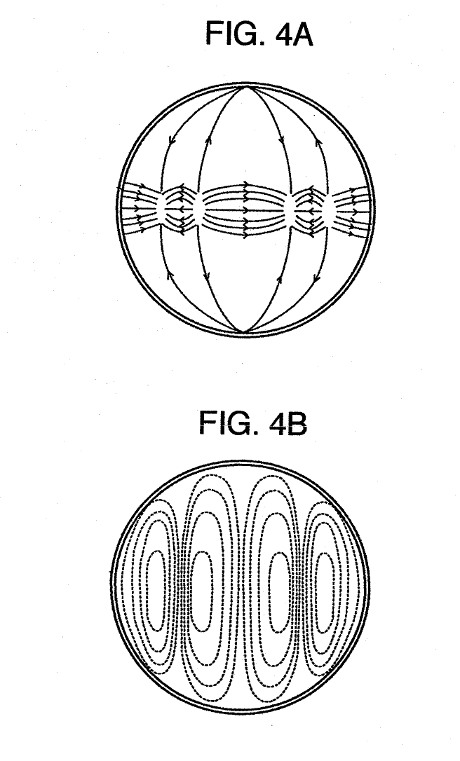

Explanation is given on distributions of an electric field and a magnetic field inside the cylindrical cavity part of the present embodiment and that of a conventional technology with reference to FIG. 3A, FIG. 3B, FIG. 4A, and FIG. 4B for comparison. FIG. 3A and FIG. 3B are diagrams schematically showing distributions of an electric field and a magnetic field inside a cylindrical cavity part according to a conventional technology.

In a conventional technology, at a connection part of a circular waveguide and a top lid of the cylindrical cavity part coupled under the circular waveguide, the surface thereof has a step and a distribution of the electric field becomes discontinuous so that there is a possibility that a stronger electric field is formed locally than at other positions and thus abnormal discharge can occur. As for this point, explanation on the distribution in the cross-section cut in a horizontal direction of the inside of the cylindrical cavity part in the conventional technology gives such a distribution of the electric field as shown in FIG. 3A. Further, at the same time, a magnetic field orthogonal to an electric field direction in this distribution is formed and applied by the solenoid coil 110. A contour distribution of lines of magnetic force of the magnetic field in this case is like the one shown in FIG. 3B.

As shown in these figures, in the conventional technology, increase and decrease in the intensity or density value of the electric field and the magnetic field inside the cylindrical cavity part just under the circular waveguide are generated at the vicinity of the center of the processing chamber 114 as peaks and valleys. Such distributions of the electric field and the magnetic field (electromagnetic field) are rotating in the circumference direction of the circular cross-section of the cylindrical cavity part; providing periodic variations corresponding to a period of one rotation thereof, it is considered that the intensity or density distribution in the radial direction of the cylindrical cavity part or the processing chamber below becomes the TM11 mode giving a maximum (peak) at a predetermined radius position, for example at a position directly under the peripheral edge part of the circular waveguide. In processing using plasma formed corresponding to such a distribution of the electric field or the magnetic field, such a problem has been raised that the influence of presence of a maximum at the vicinity of the center axis of the processing chamber such as at the radius of the cross-section of the circular waveguide shows up as a distribution of processing characteristics, for example of the etching rate in the radial direction (rate profile) on the surface of a sample to cause a variation out of an allowable range in a profile after processing in the in-plane direction of the sample depending on process conditions.

In the present embodiment described above, the second cylindrical cavity part 107 with a smaller diameter is arranged to connect above the first cylindrical cavity part 106. As described above, the inner face of the side wall at the lower end part of the side wall of the second cylindrical cavity part 107 and the lower face of the first upper face plate 106′ of the first cylindrical cavity part 106 are connected nearly perpendicular and the distribution of the electric field formed inside this connection part becomes discontinuous at the corner part protruded toward inside so to speak and a strong electric field Ez is generated locally, which is propagated downward with this connection part as a starting point.

The strong electric field Ez generated by such a discontinuous distribution of the electric field is also generated at a connection part between the circular opening of the center of the second upper face plate 107′ of the second cylindrical cavity part 107 and the lower end part of the circular waveguide 104; in the cylindrical cavity part of the present embodiment, it has Ez at two positions in the radial direction from the center axis, which are directly below the inner circumferential edge at the lower end part of the circular waveguide 104 and directly below the lower end part of the side wall of the second cylindrical cavity part 107. The superposed of such strong electric field Ez with the electric field which is propagated down from the cylindrical cavity part is propagated inside the processing chamber 114.

An electric field distribution in a cross-section in the horizontal direction inside the first cylindrical cavity part 106 in the present embodiment is shown in FIG. 4A. Further, similar to the conventional technology, a magnetic field orthogonal to an electric field direction is generated and applied by the solenoid coil 110 and the distribution thereof becomes the one shown in FIG. 4B.

As shown in this figure, the distribution of the electric field in the first cylindrical cavity part 106 in the present embodiment has the TM12 mode and by rotation of the electric field of this distribution in the circumferential direction of a cross-section of the cylindrical cavity part in a predetermined period, the intensity or density thereof varies with the period. When considered by averaging in time per unit time, the distribution of the electric field in the first cylindrical cavity part 106 in the present embodiment becomes the one strongly influenced by the electric field Ez at plural positions (two positions) in the radial direction thereof and typically the one having plural (two) maximum (peaks) in the radial direction.

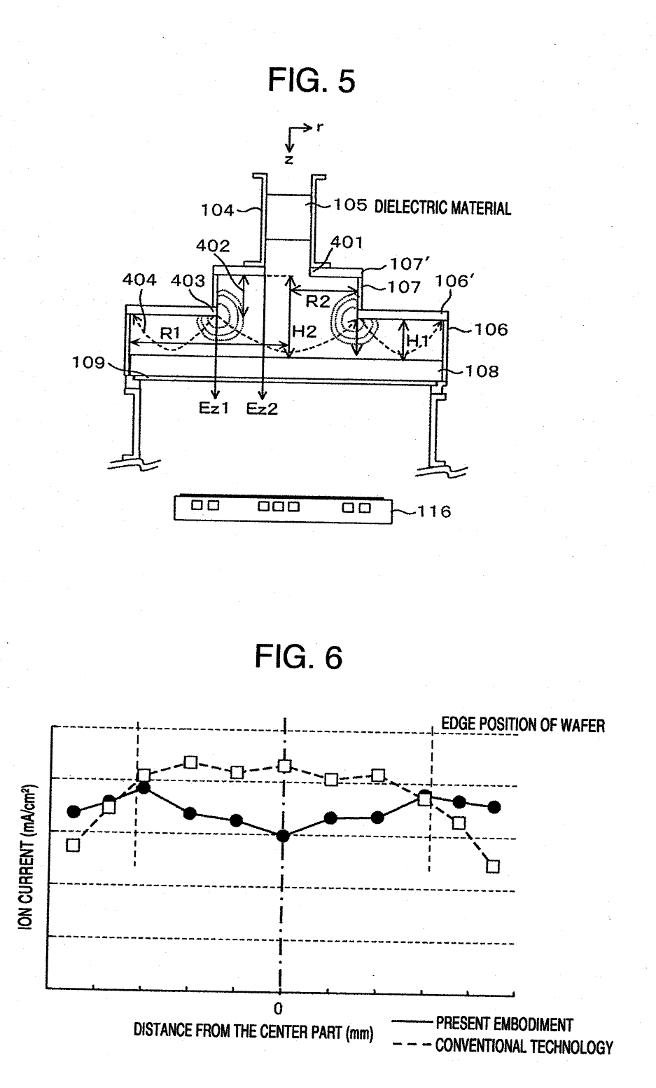

Explanation is given on the electric field in the cylindrical cavity part of the present embodiment with reference to FIG. 5. FIG. 5 is a longitudinal cross-sectional view schematically showing the electric field in the cylindrical cavity part of the present embodiment shown in FIG. 1. In particular, explanation is on generation of a standing wave when the radius of the second cylindrical cavity part 107 having the smaller radius which is connected to the first cylindrical cavity part 106 having the same radius as that of the processing chamber 114 thereabove and arranged and is connected to the circular waveguide 104 therebelow is set to satisfy λ/4<R2 with respect to a wavelength of A of the standing wave of the electric field in the cylindrical cavity part and when being set in ranges of values satisfying λ<H2<λ+λ/4 (=5λ/4) and λ/4<H1.

Incidentally, similar to the case of FIG. 2, in the present figure it is the one enlarged to show the electric field introducing part of the embodiment shown in FIG. 1, a discharge part which constitutes the processing chamber 114 and in which the plasma 115 is generated in a space of the cylindrical shape and a side wall part of the cylindrical shape of the vacuum container surrounding this are shown underneath the microwave introducing window 108; the part below the vacuum container is omitted. Also, the magnetron 101, the rectangular waveguide 102 which extends in the horizontal direction, and the like are not shown.

Furthermore, as for parts referred to with the same reference signs as in FIG. 1, explanation is omitted when explanation is not particularly needed.

In the present figure, the electric field of the microwave introduced into the second cylindrical cavity part 107 from the lower end of the circular waveguide 104 causes diffusion in the cavity part inside (primary diffusion). That is, the electric field proceeds uniformly in all directions around from the lower end of the circular waveguide 104 or the inner circumferential edge of the opening of the center part of the second upper face plate 107′. The electric field which proceeds toward the outer circumference of the second cylindrical cavity part 107 reflects at the vertical inner side wall face of the second cylindrical cavity part 107 and interferes with the following electric field diffusing so that a standing wave is generated in the second cylindrical cavity part 107 as a steady state. And, a distribution of such an electric field becomes discontinuous at the connection part 401 of the inner wall face at the lower end part of the circular waveguide 104 and the lower face of the second upper face plate 107′ which are arranged nearly perpendicular with each other, thus generating the electric field Ez2 having a higher intensity in the Z direction (toward below in the figure, a center axis direction of the circular waveguide 104 or the processing chamber 114) at this connection part 401. Such an electric field in the second cylindrical cavity part 107 is propagated down and is introduced into the first cylindrical cavity part 106 connected thereto. This introduced electric field diffuses (secondary diffusion) in the cavity in the first cylindrical cavity part 106, similar to the electric field from the circular waveguide 104 described above. Then, also at a connection part 403 constituting a step between the second cylindrical cavity part 107 and the first cylindrical cavity part 106, similar to the second cylindrical cavity part 107, a randomly reflected wavefront with this spot as its center is generated and the electric field Ez1 having a locally strong intensity in the Z direction is generated. In this way, lines of electric force 404 are generated for which sources and sinks are at the connection part 403 between the first cylindrical cavity part 106 and the second cylindrical cavity part 107 which constitutes the step inside.

In the present embodiment giving such a distribution, values of the height H1 of the first cylindrical cavity part 106 and the height H2 of the second cylindrical cavity part 107 are adjusted suitably and set so that the intensity distribution of the electric field obtained by superposing the electric field Ez2 generated directly under the peripheral edge of the lower end part of the circular waveguide 104 and the electric field Ez1 generated directly under the lower end part of the side wall of the second cylindrical cavity part 107 becomes close to be uniform by reducing non-uniformity in the radial direction (in the horizontal direction in the figure or the direction) in the processing chamber 114 arranged below or in the plane where the ECR is generated. In this way, non-uniformity of the plasma density or intensity between the center and the outer circumference of the processing chamber 114 is reduced and thus plasma with improved uniformity in the radial direction in the processing chamber 114 or from the center to the outer edge of the sample mounted on the mounting surface of the sample stage 116 below is formed.

In the present Embodiment, the effective wavelength λ of the TM12 mode in a free space is 130 to 140 mm. Therefore, it is preferable that the distance H2 from the upper face of the microwave introducing window 108 to the ceiling face of a space in the second cylindrical cavity part 107 (the lower face of the second upper face plate 107′) is set in a range of λ<H2<λ+λ/4 (=5λ/4). In addition, it is preferable that the distance H1 between the ceiling face of the first cylindrical cavity part 106 (the lower face of the first upper face plate 106′) and the upper face of the microwave introducing window 108 is set in a range of λ/4<H1 to make the above effective wavelength to be efficiently propagated and introduce into the processing chamber 114 below. Furthermore, in the present embodiment, even though the distance (radius) R1 from the center axis of the first cylindrical cavity part 106 to the side wall is equivalent to the radius of the processing chamber 114 having a cylindrical shape or the radius of the discharge part thereof, it is preferable that the distance (radius) R2 from the center axis of the second cylindrical cavity part 107 to the side wall is set in a range of λ/4<R2.

Inside the first cylindrical cavity part 106 the electric field having a distribution as a result of superposing these Ez1 and Ez2 is propagated downward. As for this distribution, in order that the plasma distribution in the processing chamber 114 formed below becomes a desired distribution, for example, a distribution having improved uniformity of the density or intensity from the center over the outer side in the radial direction, the height H1 and the radius of the first cylindrical cavity part 106 and the height 402 and the radius R2 of the second cylindrical cavity part are adjusted and set within ranges of suitable values. For example, to give the above desired gradient of the density or intensity in the radial direction, the distances H1 and H2 between the upper face of the microwave introducing window 108 and the ceiling face of the first cylindrical cavity part 106 as well as the ceiling face of the second cylindrical cavity part 107 are adjusted and set; then, processing of a sample is performed.

By satisfying such conditions, the electric field from the two cylindrical cavity parts is propagated downward and is efficiently absorbed by the ECR surface formed in the processing chamber 114. By this, the plasma that has higher densities and reduced non-uniformity from the center of the processing chamber 114 over the outer circumference is generated.

As described above, in a conventional technology, there will be such a distribution as plasma intensity or density becomes small from the center toward the outer circumference part, especially in the outer circumference part. On the other hand, in the present embodiment, regions with locally high intensities or densities of the electric field are arranged at plural positions of the outer circumference side in the radial direction from the center of the processing chamber 114. Therefore, the problem of a conventional technology that a decrease in the density or intensity shows up significantly from the center of the processing chamber 114 toward the outer circumference part is suppressed, a gradient of the density or intensity over the outer circumference part is made smaller than those with a conventional technology, and thus plasma with improved uniformity in the radial direction of the processing chamber 114 can be formed. In the present embodiment as above, as a result of confirming an ICF distribution above the sample on the sample stage and a distribution of etching processing characteristics, for example, a processing rate, a result in which uniformity is improved compared with a conventional technology has been obtained.

Also, by inserting the dielectric material 105 for generation of a circularly polarized wave into the circular waveguide 104 to change the phase of the TE11 mode in the circular waveguide 104 by 45 degrees, a uniform TE11 mode can be obtained at the incident end of the cylindrical cavity part. Therefore, by improvement of the distribution in the radial direction by the TM mode and improvement of the distribution in the circumference direction by the circularly polarized wave, an effect of improvement of uniformity of plasma generated in the processing chamber 114 can be obtained altogether. It is needless to say that a distribution of radicals obtained by such plasma becomes effective for isotropic etching of a film of the processing object on the top surface of the sample. In this way, a plasma processing apparatus having improved processing performance for a large diameter sample can be provided.

Adjustment of a shape of the cylindrical cavity part of the present embodiment can be performed by displacing vertical positions of the first upper face plate 106′ and the second upper face plate 107′ by a user as for the heights H1 and H2. Incidentally, although not shown, at outer circumferential edge parts of the first upper face plate 106′ and the second upper face plate 107′ devices for suppressing leakage of an electric field such as choke flanges which make short-circuit for the side walls and the upper face plates along with a relative displacement with the side walls are provided.

In addition, the radius R2 of the second cylindrical cavity part 107 of the present embodiment is set to a smaller value than the radius from the center axis to the external shape of the sample stage 116 which is arranged below and has a cylindrical shape. Also, it is set to a larger value than the radius position of the outer circumferential edge of the mounting surface arranged on the upper face of the sample stage 116; that is, it is arranged at a position of the outer circumference side from the outer circumferential edge of the sample mounted thereon. By such an arrangement, a place (radius position) of a high density of the electric field by the electric field Ez1 generated at the connection part 403 can be formed inside of the external shape of the sample stage 116 and on the outer circumference side of the sample. In this way, arising such a problem of a conventional technology can be suppressed that the distribution of plasma density or intensity in the radial direction of the sample largely decreases at the outer circumference side part of the sample and processing characteristics in the radial direction becomes non-uniform and thus plasma processing with further improved uniformity can be performed by the electric fields Ez1 and Ez2 generated at the radial positions corresponding to the positions of the connection part 403 and the connection part 401.

Explanation is given on functions and effects of the present embodiment with reference to FIG. 6. FIG. 6 is a graph showing distributions of ion currents (ICF distributions) in an in-plane direction of a sample from the plasma 115 in the processing chamber 114 to an electrode in a sample stage 116 of a conventional technology and the present embodiment shown in FIG. 1. In an embodiment of the present figure, they are results obtained when the process gas used to form plasma 115 is a mixture gas of Cl₂/HBr/O₂/Ar, the pressure inside the processing chamber 114 is 0.4 Pa, the height of the ECR surface from the surface of the mounting surface of the sample stage 116 is 165 mm, and supplied microwave power is 1200 W in the case of a conventional cylindrical cavity part and 1800 W in the present embodiment.

In the conventional technology, a distribution of the ion current that is high at the center part and low at the outer circumference part is shown. Therefore, plasma distribution has a convex-type shape. In particular, decrease in the ion current density is prominent in the region of the outer circumference part of the sample (150 mm or more),and it is considered that large decrease takes place in the outer circumference side part similarly in the density or intensity of the plasma 115. Further, processing uniformity in an in-plane direction of the sample by the conventional technology at these conditions was 11%.

On the other hand, in the case of the present embodiment, it is shown that the ion current becomes high at the vicinity of 150 mm in the radial direction from the center of the sample stage 116. On the other hand, the distribution low in ICF at the center and the outer circumference part of the sample is shown. That is, the plasma intensity or density at the above conditions of the present embodiment shows a distribution of an M-type shape. Further, processing uniformity in an in-plane direction of the sample at the conditions became 5%.

The above detected data show results of the best uniformities among those detected in processing at plural conditions by varying microwave power to plural values as well as the height of the ECR surface, respectively. Besides, a result of improvement of uniformity was also obtained at process conditions for fluoride systems.

In addition, it is needless to say that, because radicals are irradiated uniformly onto a wafer in a state of high uniformity, it is also advantageous for radical-induced etching. In particular, at high pressure conditions (3 Pa to 10 Pa), the degrees of diffusion of electrons and ions electrically dissociated are large and radicals become dominant rather than ions on the wafer to improve variations of profiles or rates in-plane of a wafer even at high pressure.

As described above, according to the present embodiment, a plasma processing apparatus can be provided in which non-uniformity of the distribution of a density or intensity of the plasma formed inside the processing chamber and uniformities of processing characteristics or processing profiles in the radial direction of the sample.

### Embodiment 2

Explanation is given next on another embodiment of the present invention.

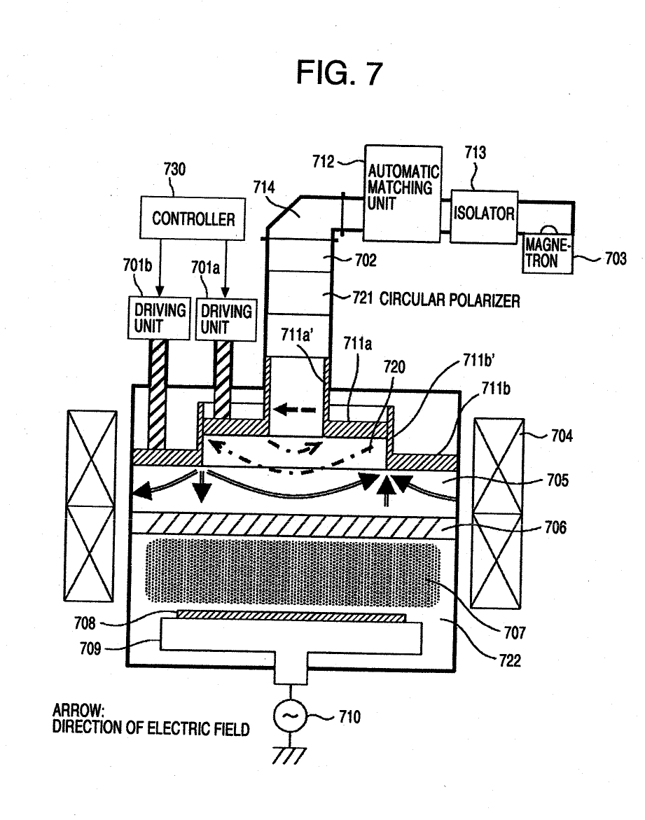

FIG. 7 is a longitudinal cross-sectional view showing a schematic configuration of a plasma processing apparatus according to another embodiment of the present invention. In this figure, the plasma processing apparatus is the one comprising a vacuum container and a processing chamber inside thereof and in which plasma is formed by exciting reactive gas supplied into the processing chamber as introducing a magnetic field from a magnetic field generation apparatus arranged at the outer circumference (lateral and above) of the processing chamber while as introducing an electric field of a microwave band in the processing chamber through a conduit to propagate the electric field arranged above the vacuum container. At the lower part in the processing chamber a sample stage is arranged for mounting a sample such as a semiconductor wafer on its upper face and the sample mounted and retained on the sample stage is subjected to processing by plasma such as etching.

A microwave excited by a magnetron 703 arranged at an end part of the conduit for propagating a electric field of the plasma processing apparatus shown in FIG. 7 travels left in the figure in the conduit extending in a horizontal direction (a left-to-right direction in the figure) and having a rectangular cross-section, is introduced downward into a circular waveguide 702 coupled at the end part thereof and having a circular shape cross-section, and is introduced into a cavity part connected to the lower end part thereof and having a circular shape cross-section in a horizontal direction.

The cavity part is a part which has a space of a cylindrical shape inside and the lower face of the space is constituted of a window member of a circular shape made of a dielectric material such as ceramics (for example, quartz) through which the electric field of the microwave band can be transmitted. The ceiling plate part constituting the ceiling face at the upper part thereof is divided into plural (two in the present figure) regions concentrically. Further, the center side and the circumference side among these regions are configured so that distances between the ceiling plate and the window member made of a dielectric material, that is, heights of the cavity parts become different. Namely, the ceiling plate of the cavity part has two regions concentrically and they are configured to be arranged with a step between them.

The electric field by the microwave introduced through the circular waveguide 702 into the cavity part comprising regions, each of which is adjacent with each other via such a step and has a different height, respectively, is introduced into a upper cavity part (a first cavity part 720) first. The electric field of the microwave introduced into the first cavity part 720 reflects at the step portion between both parts including a boundary part with a lower cavity part (the second cavity part 705) to generate a standing wave inside the first cavity part 720. Then, at the lower end part of the step portion, which is the boundary part between the first cavity part 720 and the second cavity part 705, intensity of the electric field is concentrated and becomes high unevenly to generate the electric field in a direction perpendicular to the window member made of a dielectric material, the upper face of the sample stage arranged in the processing chamber below, or the upper face of a sample mounted thereon.

By the electric field in the direction perpendicular to this sample or the like, the TM11 mode is excited in the second cavity part 705. By this TM11 mode, the plasma density is enhanced in a region inside the processing chamber corresponding to a position of the boundary described above. In particular, by arranging such a boundary part at a position of a predetermined radius from the center of the sample, the plasma uniformity in the circumference direction is enhanced at the corresponding outer circumference side (peripheral region) of the sample.

On the other hand, because at a position where to a region positioned directly under the circular waveguide 702 (including a region projecting under the tube part of the circular waveguide 702) the TE11 mode electric field of the microwave is introduced from above, that is, where it is directly introduced the electric field contributes to increase of the plasma density at the center, uniformity of the plasma density distribution improves as a whole in combination with increase in the plasma density of the circumference part.

In addition, according to investigation of the present inventors, by lowering the height of the cavity part of the circumference side region than the center part an influence of the TM11 mode increases and the plasma density at the corresponding circumference part increases.

On the other hand, such knowledge was obtained that by lowering the cavity height at the center side an influence of the TE11 mode increases and the plasma density at the center part increases. In the following embodiments, based on the above knowledge, by variably adjusting the heights of the cavity parts at plural regions arranged concentrically of the center side and the circumference side respectively to be at positions of relative arrangements suitable for processing conditions of the sample, uniformity of the distribution of the plasma density and consequently processing can be enhanced, resulting in attainment of processing with high reproducibility and precision.

For example, when there is a tendency that the plasma density becomes high at the center part in the case of performing processing at high pressure conditions inside the processing chamber, the cavity height of the circumference side is arranged low and the cavity height of the center side is arranged high in order to enhance the plasma density of the circumference part. When the processing pressure is low, the reversed method is performed.

As for the ceiling face of each cavity part in such regions of the center side and the circumference side, the plasma density distribution is detected by measurement of plasma emission intensity in each of the center part and the circumference part and the positions in the height direction may be changed accordingly. Also, the number of division of the upper face of the cavity part is not limited to two and it may be three or more. For example, when divided into three, the TM12 mode is excited in addition to the TM11 mode and the plasma densities at three places of the center part, the intermediate part, and the circumference part can be varied independently.

Explanation is given below in detail. In the present figure, the electric field of the microwave band is generated and excited by a magnetron 703 arranged at one end (the right end in the figure) part of the waveguide having a rectangular shape cross-section and passes through the parts of an isolator 713 and an automatic matching unit 712 arranged on the waveguide to be propagated toward the left side in the figure. At the other end (the left end in the figure) part of the rectangular waveguide, the waveguide is connected to the circular waveguide 702 of a circular shape cross-section extending in the vertical direction with a rectangle-circle conversion waveguide 714 in between. In the rectangle-circle conversion waveguide 714 the electric field being propagated from the right side toward the left side in the figure changes the direction to downward and is introduced into the circular waveguide 702 for which the axis of the tube thereof is extending in the vertical direction (a vertical direction in the present embodiment).

The circular waveguide 702 is connected to the rectangle-circle conversion waveguide 714 at the upper end part thereof and connected at the lower end part to the cylindrical shape cavity part arranged above the vacuum container at the center part thereof, as described above. At a place between the upper and lower end parts of the circular waveguide 702 a circular polarizer 721 is mounted and the microwave introduced into the circular waveguide 702 is converted to a circularly polarized wave and introduced into the cavity part.

Namely, the electric field is rotated clockwise or counter-clockwise in a direction of propagation of the electric field and is propagated downward. In this way, non-uniformity of the plasma density or intensity in the circumference direction in a processing chamber 722 arranged in the vacuum container under the cavity part and a window member 706 made of quartz is reduced.

The upper face of the cavity part has a nearly circular shape matching to a space of a cylindrical shape inside the cavity part and as members constituting the ceiling face circular shape or ring shape ceiling plates in regions corresponding to ranges of different distances in the radial direction from the center of the space are arranged. In the present embodiment, two regions are divided into and arranged to be constituted each by a center ceiling plate 711a and a circumference ceiling plate 711b.

The center ceiling plate 711a comprises a ring-like plate part configuring the center part of the upper face of the cavity part having a cylindrical shape and a columnar conductor 711a′ extending in the vertical direction from the end part of the inner circumference side of this plate part and coupled to the inside of the circular waveguide 702. These are moved in the vertical direction as one unit using a driving apparatus 701a such as a pulse motor connected to the upper face of the ring-like plate part so that it is configured to variably adjust the distance (height) with the window member 706 made of a dielectric material.

The columnar conductor 711a′ is arranged so that the cylindrical shape outer side wall thereof is inserted inside the circular waveguide 702 and overlaps with the inner wall face thereof. Namely, it is arranged so that the outer side wall of the upper end part of the columnar conductor 711a′ and the inner side wall of the lower end part of the circular waveguide 702 face each other and overlap either mutually in contact or with a tiny gap apart even when the plate part of the center ceiling plate 711a is displaced to the lowest position. Both members are in contact to make the inside of the cavity part as a single space electrically or connected in proximity to be considered as a single space.

Also, the circumference ceiling plate 711b is configured to comprise a ring-like plate part configuring the periphery part of the upper face of the cavity part and a columnar conductor 711b′ extending in the vertical direction from the inner circumferential edge part of this plate part and coupled to form a step between this plate part and the outer circumferential edge part of the ring-like plate part of the center ceiling plate 711a. These are moved in the vertical direction as one unit using a driving apparatus 701b such as a pulse motor connected to the upper face of the ring-like plate part so that it is configured to variably adjust the distance (height) with the window member 706 made of a dielectric material.

The columnar conductor 711b′ is arranged so that the inner side wall face having a cylindrical shape thereof is in contact with the part of an outer circumferential edge of the center ceiling plate 711a or coupled thereto facing in a horizontal direction with a tiny gap in between. These are arranged so that the positions thereof overlap in the height direction and, the inner side wall of the columnar conductor 711b′ is configured to oppose to the outer periphery of the center ceiling plate 711a either in contact or via a tiny gap even when the plate part of the center ceiling plate 711a is positioned at the highest position and the plate part of the circumference ceiling plate 711b is positioned at the lowest position. In addition, they are arranged so that the plate part of the center ceiling plate 711a will never be positioned lower than the plate part of the circumference ceiling plate 711b, that is, the distance (height) of a space in the cavity part from the window member 706 at the center part is equal to or greater than at the circumference part.

A cylinder shape metallic member positioned at the outer circumference side of the circumference ceiling plate 711b of the present embodiment and opposing in a horizontal direction in contact or via a tiny gap to its outer circumferential edge which moves up and down is arranged toward the top of the vacuum container to constitute a side wall face of the cavity part. In the present embodiment, a member constituting the side wall face is constituted by a cylinder shape having nearly the same diameter as that of the cylinder shape outer circumference side wall of a cylinder shape space part (discharge part) in which plasma 707 in the processing chamber 722 is formed toward the top part of the processing chamber 722 or the vacuum container constituting this and is coupled to the outer circumferential edge part of the plate part of the circumference ceiling plate 711b. As well as for the height position (distance from the upper face of the window member 706) of the upper end part of this side wall member, even when the plate part of the circumference ceiling plate 711b is displaced to the highest position, it is coupled to the outer circumference part of the circumference ceiling plate 711b.

The cavity part of the present embodiment is divided to plural parts configured by regions corresponding to the center ceiling plate 711a and the circumference ceiling plate 711b which are coupled with a step as described above and adjacent in the radial direction of the cavity part. A circular column-like (cylinder-like) space above configured by the plate part of the center ceiling plate 711a and the columnar conductor 711b′ part of the circumference ceiling plate 711b is called the first cavity part 720. Further, a circular column-like (cylinder-like) space below configured by the ring-like plate part of the circumference ceiling plate 711b and the inside wall of the circular column-like side wall member which constitutes the side face of a space of the cavity part is called the second cavity part 705.

The cavity part is composed as one space by adjoining both in the vertical direction with the lower face of the former and the upper face of the latter connected in series. A ceiling face of the cavity part has a step constituted of the columnar conductor 711b′ between the ceiling face of the first cavity part 720 composed of a plate part of the center ceiling plate 711a and the ceiling face of the second cavity part 705 composed of a plate part of the circumference ceiling plate 711b and, thus, the height is changed stepwise in the radial direction from the cylinder-like center axis thereof. By this step, a difference of the distribution of the electric field is formed between inside the first cavity part 705 and the second cavity part 720.

Incidentally, the columnar conductor 711a′ of the center ceiling plate 711a is coupled to the inner side wall of the circular waveguide 702 and inserted inside and, thus, the electric field which is propagated down in the circular waveguide 702 travels down the space inside the cylindrical shape columnar conductor 711a′ to be introduced into the upper end part of the above-described first cavity part 720. The columnar conductor 711a′ is a conduit functioning as an extension part of the circular waveguide 702 and the lower end part thereof is connected to the upper end part of the center of the first cavity part 720. The electric field of the microwave introduced from the circular waveguide 702 (a conduit inside the columnar conductor 711a′) into the first cavity part 720 reflects on the inside wall face of the columnar conductor 711b′ including the boundary between the first cavity part 720 and the second cavity part 705 and a standing wave is generated inside the first cavity part 720 (the long dashed short dashed line in FIG. 7). Then, at the lower end part of the columnar conductor 711b, which is the boundary part between the first cavity part 720 and the second cavity part 705, an electric field is generated in a direction perpendicular to the window member 706, the mounting surface of the upper face of a wafer stage 709 arranged inside the processing chamber 722 underneath thereof, or a wafer 708 mounted thereon so that by the electric field in the vertical direction to this wafer the TM11 mode is excited.

In a state that the wafer 708 is mounted on the wafer stage 709 arranged at the lower part in the processing chamber 722 and retained by an electrostatic chuck, reactive gas for processing (process gas) is introduced into the processing chamber 722 from a gas introducing passage which is not shown through plural introducing holes in a shower plate arranged with a clearance with the lower face of the window member 706 and constituting the ceiling face of the processing chamber 722 and by the ECR (Electron Cyclotron Resonance) between the above electric field of the microwave band and a static magnetic field generated by a solenoid coil 704, which is the magnetic field forming device, particles of the reactive gas are excited to form plasma 707. At the inside of the wafer stage 709 which has a cylindrical shape and is arranged so that the center axis thereof coincides with the center axis of the processing chamber 722 a not-shown electrode made of an electric conductor is arranged and an RF power supply 710 for generating a radio frequency is connected electrically to this electrode. While the plasma 707 is formed, the radio frequency is applied to the electrode from the RF power supply 710 to form a bias potential over the top surface of the wafer 708 and charged particles inside the plasma 707 are attracted by the potential difference between the plasma 707 and the bias potential toward an top surface of the wafer 708 so that by interaction caused by collision between them etching of a processing object film arranged on the top surface of the wafer 708 is performed.

The lower end part of the columnar conductor 711b′ is arranged in a circumference way at a predetermined radial distance from the center axis of the cavity part or of the processing chamber 722 which has the same diameter as this or a similar diameter to presumably the same and in the region with this predetermined radial distance inside the processing chamber 722 including a place directly below the window member 706 plasma influenced by the TM11 mode electric field is formed strongly; in this region plasma superior in uniformity of the density or intensity in the circumference direction at a radius of a predetermined value is formed accordingly. Incidentally, the lower face of the window member 706 and the mounting surface in the upper face of the wafer stage 709 are arranged in parallel or in relative arrangement presumably in parallel.

On the other hand, the electric field of the microwave which is propagated inside the circular waveguide 702 has the TE11 mode and in the electric field distribution in the cavity part directly under the circular waveguide 702 and including a projected plane thereof or a space including an area of the circular shape window member 706 or of the cylinder-like processing chamber 722 having nearly the same shape as this at the center the electric field of the TE11 mode yields a dominant or strong influence. That is, the electric field of the TM11 mode microwave described above and the electric field of the TE11 mode microwave directly introduced from the circular waveguide 702 are introduced into the processing chamber 722 as being transmitted through the window member 706. And, as for the density or intensity of the electric field in the processing chamber 722, there exists a region where such plasma is formed that is influenced strongly by the TE11 mode electric field in the radial direction from the center axis thereof and a region where such plasma is formed that is influenced by the TM11 mode electric field at the circumference side in the radial direction.

A distribution of the density and intensity of the plasma generated by superposing these electric fields with different modes becomes the one with uniformity in the radial direction improved. Namely, the plasma formed by the TE11 mode electric field is formed strongly at the center side and the plasma formed by the TM11 mode electric field is formed strongly at the outer circumference side; by mutually complimenting a region where the intensity or density decreases uniformity of characteristics of such as the plasma density or intensity in a surface direction thereof is improved over the wafer 708.

Incidentally, the distance from the center axis of the cavity part of the columnar conductor 711b′ of the present embodiment, that is, the center axis of the processing chamber 722 or a cylindrical shape wafer stage, is set at equal to or shorter than a value of the distance to the outer circumferential edge of the upper face of the wafer stage 709 (radius of the upper face of the wafer stage 709) and desirably equal to or shorter than a value of the radius of the wafer 708. By adopting such a configuration, the distribution of the density or intensity of the plasma strongly influenced by the TM11 mode electric field described above is maintained to have high uniformity up to the outer circumferential edge of the wafer 708.

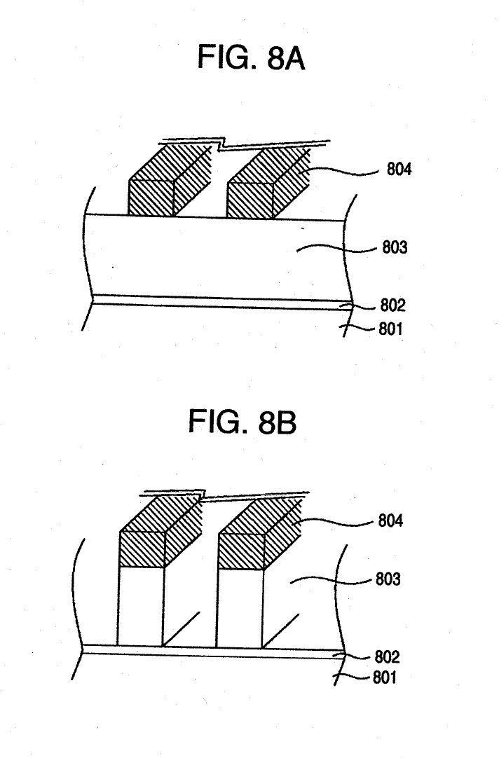

FIG. 8A and FIG. 8B are schematic diagrams showing examples of film structures arranged at the top surface of the wafer 108 to be processed using the plasma processing apparatus according to the embodiment shown in FIG. 7. In the present example an example of forming a semiconductor device circuit by etching processing from the film structure is shown.

FIG. 8A and FIG. 8B show the cross-section of the film structure before and after etching processing, respectively. As a state before processing an oxide film 802 and a poly-Si film 803 are formed on a silicon substrate 801. On the poly-Si film 803 a resist 804 with a transcribed circuit pattern is present. Using the microwave plasma etching apparatus shown in FIG. 7 the poly-Si film 803 of a part not covered with the resist 804 is removed to provide a state after processing shown in FIG. 8B. At this time, the oxide film 802 is not removed.

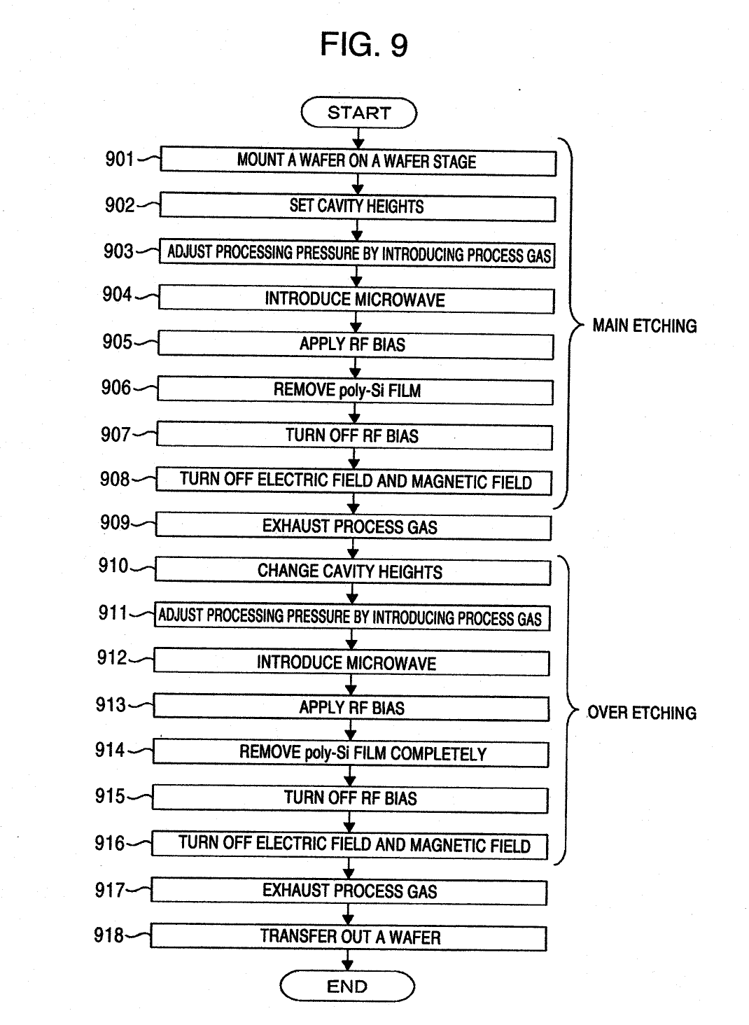

FIG. 9 is a flowchart showing a flow of an operation when the film structures shown in FIG. 8A and FIG. 8B are processed with the plasma processing apparatus according to the embodiment shown in FIG. 7. At the step 901 of the present figure, the wafer 708 is mounted on the mounting surface of the wafer stage 709 as being mounted on a transfer apparatus such as a robot arm which is not shown in the processing chamber 722 and adhered and retained on the mounting surface by an electrostatic chuck. In this state the so-called main etching for removing a large part of the poly-Si film 803 is performed.

In the present embodiment, at the step 902, the heights of respective plate parts of the center ceiling plate 711a and the circumference ceiling plate 711b, the lower faces of which constitute the ceiling face of the cavity part, are input by a user of the plasma processing apparatus and set by transmitting commands. Data, into which values obtained by an experiment or the like in advance to yield desired distributions of characteristics such as the plasma density or intensity in the processing chamber 722 are memorized in a memory unit in a controller 730 of the plasma processing apparatus, are read out by a calculator of the controller 730 and sent to the driving units 701a and 701b such as pulse motors via an input-output interface so that respective heights are set by their operations.

At the step 903, process gas is introduced into the processing chamber 722 from the introducing holes in the shower plate and a balance between this flow amount and rate and the flow amount and rate of evacuation of the inside of the processing chamber 722 from an exhaust port under the processing chamber 722 is adjusted to set the pressure inside the processing chamber 722 within a range of desired values. Exhaust from the exhaust port is performed with a vacuum pump, which is not shown, coupled to the lower face of the vacuum container; particles of plasma, gas, products, and the like in the processing chamber 722, which is evacuated by operation of the vacuum pump performed even during processing, are exhausted to the outside of the plasma processing apparatus or the outside of a building where this is installed.

At the step 904, the electric field of the microwave band is introduced from the circular waveguide 702 through the cavity part via the window member 706 into the processing chamber 722 and a magnetic field from the solenoid coil 704 is further supplied into the processing chamber 722 so that the process gas is excited by their interaction and the plasma 707 is formed. At the step 905, radio frequency power is supplied to the wafer stage 709 to form a RF bias on the wafer 708 and etching of the poly-Si film 803 is started.

By using collision of charged particles such as ions with a film structure on the wafer 708 removal of the poly-Si film 803 of a processing object film progresses to perform machining of the object film to expected profiles of channels, holes, or the like along a shape of the resist 804 which serves a mask (the step 906). When it is detected that a large part of the poly-Si film 803 is removed so that the oxide film 802, which is a film thereunder, is exposed or reached just before to be exposed, supplies of the RF bias, the microwave electric field, and the magnetic field are turned off (stopped) by the step 907 and the step 908 and the plasma 707 is once extinguished. Next, supply of the process gas into the processing chamber 722 is stopped or the gas is switched to inert gas such as argon and supplied to exhaust the process gas and particles of products and the like formed during processing in the processing chamber 722 from inside the processing chamber 722 (step 909).

Next, after the main etching processing described above, so-called over-etching processing to further remove the poly-Si film 803 remained on the oxide film 802 is performed. First, heights of respective plate parts of the center ceiling plate 711a and the circumference ceiling plate 711b are changed by the step 910. As for these heights data in which values obtained in advance by an experiment or the like are memorized are read out and they are set by movements of the center ceiling plate 711a and the circumference ceiling plate 711b as command signals.

At this time, in the over-etching processing pressure during processing in the processing chamber 722 is increased in the present embodiment because it is necessary to increase selectivity between the oxide film 802 as an underlying film and the poly-Si film 803. In the present embodiment, in order to form plasma of high uniformity under such conditions the height of the circumference ceiling plate 711b is lowered relative to an arrangement of cavity heights of the center part and the circumference part during the main etching.

In this way, as compared with the case of the main etching, the height of the circumference ceiling plate 711b is set lower than the height of the plate part of the center ceiling plate 711a; that is, the ratio of the distance between the ceiling face of the first cavity part 720 and the upper face of the window member 706 and the distance between the ceiling face of the second cavity part 705 and the upper face of the window member 706 is set higher in the over-etching than in the main etching. In this way, even at the over-etching conditions, at which the pressure is set higher than in the main etching, the plasma uniformity can be improved.

After the heights at the center part and at the circumference part of the cavity part are changed by the step 910, the process gas is introduced by the step 911 to adjust the pressure in the processing chamber 722. An electric field due to the microwave and a magnetic field are introduced by the step 912 to form the plasma 707 from the process gas. Then, at the step 913, an RF bias potential is formed by power from the RF power supply to perform over-etching, in which the poly-Si film 803 is removed from corner parts of processed profiles such as channels, holes, and the like thereof (the step 914). After the poly-Si film is removed, the RF bias, the microwave electric field, and the magnetic field are turned off (stopped) by the step 915 and the step 916 and the plasma 707 is extinguished to terminate the over-etching. After the process gas is exhausted at the step 917, the wafer is transferred out at the step 918.

### Modified Embodiment 1

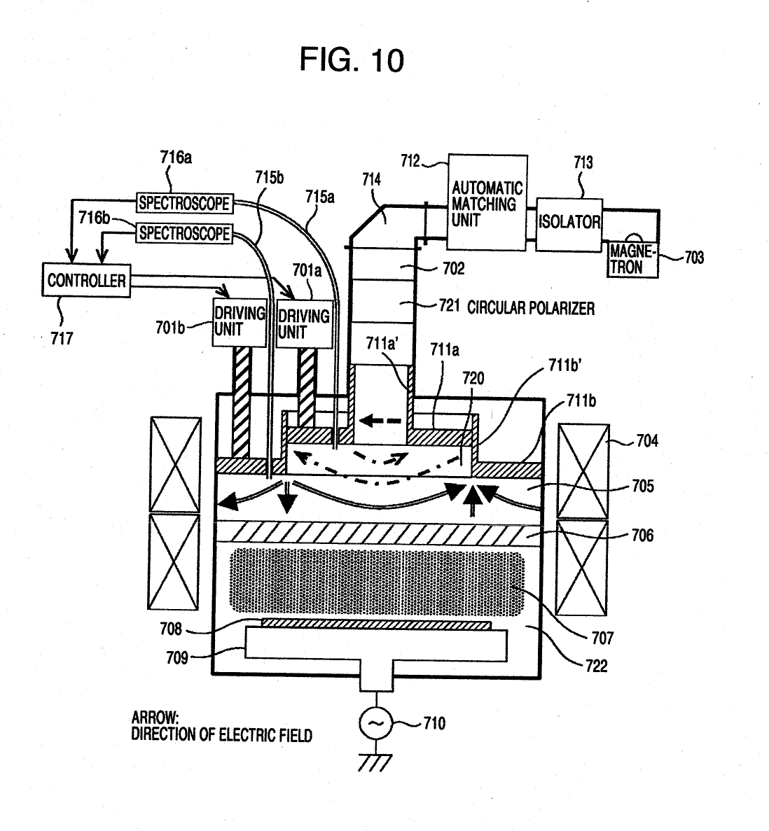

Explanation is given next on a modified embodiment of the present invention with reference to FIG. 10. FIG. 10 is a longitudinal cross-sectional view showing a schematic configuration of a modified embodiment of the plasma processing apparatus according to the embodiment shown in FIG. 7. In the present figure, explanation is omitted as for the same composition as that explained in FIG. 7, FIG. 8A, and FIG. 8B.

In the present modified embodiment, a detector is arranged to detect emission inside the processing chamber 722 during processing on each plate of the center ceiling plate 711a and the circumference ceiling plate 711b which constitute the ceiling face of the cavity part. At different positions in the radial direction, in particular, at positions in the ceiling face of the cavity part corresponding to regions of the first cavity part 720 and the second cavity part 705, parameters such as intensity of the emission correlating to the plasma density or intensity are detected in a controller 717 and based on these the heights of the respective plates of the center ceiling plate 711a and the circumference ceiling plate 711b from the upper face of the window member 706 are adjusted.

In more detail, in the modified embodiment shown in FIG. 10, each of spectroscopes 716a and 716b connected to optical fibers 715a and 715b is arranged in a ring-like plate part of the center ceiling plate 711a and a ring-like plate part of the circumference ceiling plate 711b to detect emission intensity of the plasma during processing formed inside the processing chamber 722 from above the window member 706 through an opening of each plate part. Because intensity of the emission is generally considered to be proportional to the plasma density, a value of the plasma density or intensity in each part or a ratio is detected from emission intensity output and detected from each of the spectroscopes 716a and 716b.

In the present modified embodiment, densities of the plasma at the center part corresponding to the center ceiling plate 711a and the plasma at the circumference part corresponding to the circumference ceiling plate 711b are detected respectively and compared; from the results thereof, the calculator in the controller 717 calculates suitable values of heights of respective plate parts of the center ceiling plate 711a and the circumference ceiling plate 711b, which are suitable for the distribution of the plasma density or intensity in the radial direction inside the processing chamber 722 to come close to a expected one, from a program, a data table, or the like which is memorized in advance in the memory unit. Command signals to realize the calculated values of heights are sent from an input/output interface of the controller 717 to the driving units 701a and 701b such as pulse motors and by adjusting their operations the heights of the center and circumference (outer circumference) parts of the cavity part are realized.

In the present modified embodiment, when emission intensity is weaker in the circumference part compared with in the center part, the driving unit 701b such as a pulse motor is driven by the controller 717 to lower the circumference ceiling plate 711b to increase the plasma density of the circumference part. On the other hand, when emission intensity is weaker in the center part compared with in the circumference part, the driving unit 701a such as a pulse motor is driven by the controller 717 to lower the center ceiling plate 711a to increase the plasma density of the center part.

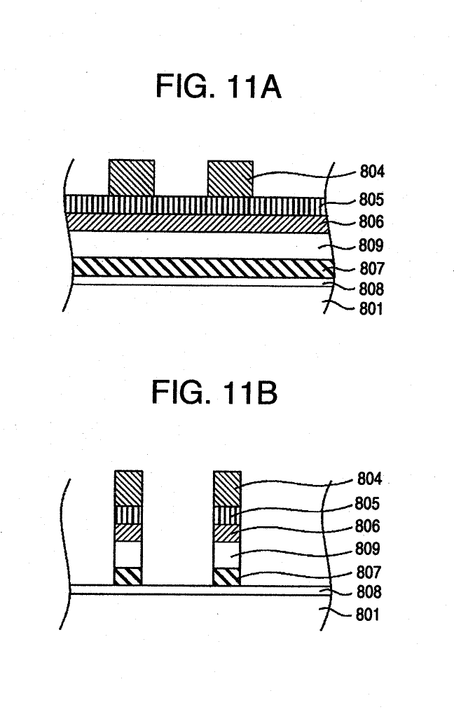

FIG. 11A and FIG. 11B are schematic diagrams showing other examples of film structures shown in FIG. 8A and FIG. 8B, which are arranged at the top surface of the wafer 708 to be processed with the plasma processing apparatus according to the embodiment of the present invention. Also in the present example, an example of forming a semiconductor device circuit by etching processing from the film structure is shown and it is an example of the semiconductor device circuit of a multi-layered film structure. FIG. 11A shows one before etching processing and FIG. 11B shows one after processing.

As a state before etching processing, a high dielectric constant film 808, a metal gate material 807, a gate material 809, a mask material 806, and an antireflection film 805 are arranged in the order from below on a silicon substrate 801 and a resist 804 to which a circuit pattern is transcribed is present on the antireflection film 805. In etching processing of a semiconductor circuit of the multi-layered film structure as described above, optimal gas system and processing pressure for etching processing of respective film material are different with each other. In the case of processing such a film structure, in the present modified embodiment, highly precise etching processing is performed by optimally adjusting the heights of respective parts of the center side part and the outer circumference side part of the cavity part corresponding to differences in gas system and processing pressure to improve uniformity of the density or intensity of the formed plasma.

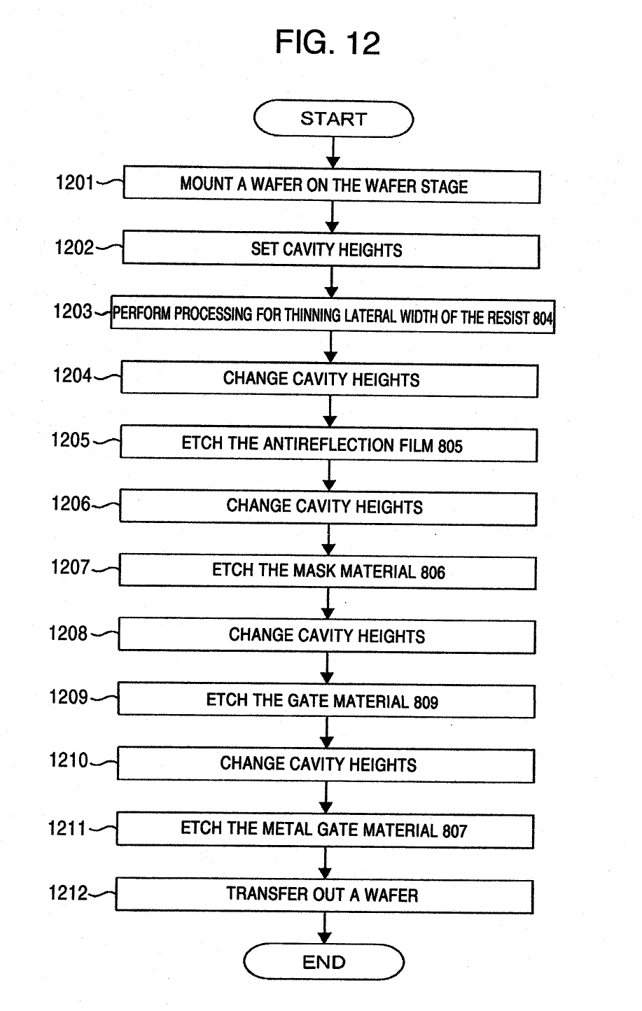

FIG. 12 is a flowchart showing a flow of an operation when the plasma apparatus according to the embodiment shown in FIG. 7 or FIG. 10 performs etching processing of the film structures shown in FIG. 11A and FIG. 11B. First, at the step 1201, similar to the embodiment shown in FIG. 9, the wafer 708 is transferred into the processing chamber 722 and mounted on the upper face of the wafer stage 709 inside.

Next, at the step 1202, the heights of the respective ring-like plate parts of the center ceiling plate 711a and the circumference ceiling plate 711b are input by a user or calculated by a calculator in the controller 717 and set by transmitting operation commands to the driving units of the respective plate parts. These heights are values obtained by an experiment or the like in advance as the conditions for obtaining high plasma uniformity at the following step 1203.

After that, at the step 1203, a mixture gas of O₂ gas and Ar gas is introduced into the processing chamber 722, at a processing pressure of 1.0 Pa plasma is formed with supply of an electric field and a magnetic field, the RF power is supplied to the wafer stage 709, and etching of the antireflection film 805 is started. Simultaneously to this, processing is performed for thinning the lateral width of the resist 804.

Subsequently, at the step 1204, the heights of the respective ring-like plate parts of the center ceiling plate 711a and the circumference ceiling plate 711b are changed. Values of these heights are also those associated with values detected by an experiment or the like in advance for the conditions to obtain plasma of high uniformity in processing of the following step 1205.

After that, at the step 1205, species and composition of process gas are changed, a mixture gas of HBr gas, O₂ gas, and Ar gas is introduced into the processing chamber 722, plasma is formed at a pressure of 0.4 Pa, and etching processing of the antireflection film 805 is performed until the under-layer mask material 806 is exposed.

The height of the plate part of the circumference ceiling plate 711b is set higher for the one at the step 1205, compared with the one at the step 1203. Alternatively, a ratio of the distance between the ceiling face of the first cavity part 720 and the upper face of the window member 706 and the distance between the ceiling face of the second cavity part 705 and the upper face of the window member 706 is set lower for the one at the step 1205 compared with the one at the step 1203.

Subsequently, at the step 1206, the heights of the respective ring-like plate parts of the center ceiling plate 711a and the circumference ceiling plate 711b are changed. Also regarding these heights, they are values obtained by an experiment or the like in advance to obtain plasma of high uniformity in processing of the following step 1207.

At the step 1207, species and composition of process gas are changed, a mixture gas of SF₆ gas, CHF₃ gas, and Ar gas is introduced into the processing chamber 722, plasma is formed at a processing pressure of 1.2 Pa, and the mask material 806 is etched until the gate material 809 is exposed. The height of the plate part of the circumference ceiling plate 711b is set lower for the one at the step 1207 compared with the one at the step 1205. Alternatively, a ratio of the distance between the ceiling face of the first cavity part 720 and the upper face of the window member 706 and the distance between the ceiling face of the second cavity part 705 and the upper face of the window member 706 is set higher for the one at the step 1207 compared with the one at the step 1205.

Subsequently, at the step 1208, the heights of the respective ring-like plate parts of the center ceiling plate 711a and the circumference ceiling plate 711b are changed. Also regarding these heights, they are values obtained by an experiment or the like in advance to obtain uniform plasma in processing of the following step 1209.

At the step 1209, using a mixture gas of CF₄ gas, Cl₂ gas, and N₂ gas and at a processing pressure of 0.4 Pa, the gate material 809 is etched until the metal gate material 807 is exposed. The height of the plate part of the circumference ceiling plate 711b is set higher for the one at the step 1209 compared with the one at the step 1207. Alternatively, a ratio of the distance between the ceiling face of the first cavity part 720 and the upper face of the window member 706 and the distance between the ceiling face of the second cavity part 705 and the upper face of the window member 706 is set lower for the one at the step 1209 compared with the one at the step 1207.

Subsequently, at the step 1210, the heights of the respective ring-like plate parts of the center ceiling plate 711a and the circumference ceiling plate 711b are changed. Also regarding these heights, they are values obtained by an experiment or the like performed in advance to obtain uniform plasma in processing of the following step 1211.

At the step 1211, using a mixture gas of Cl₂ gas, CHF₃ gas, and N₂ gas, and at a processing pressure of 0.5 Pa, the metal gate material 807 is etched until the high dielectric constant film 808 is exposed. The height of the plate part of the circumference ceiling plate 711b is set lower for the one at the step 1211 compared with the one at the step 1209. Alternatively, a ratio of the distance between the ceiling face of the first cavity part 720 and the upper face of the window member 706 and the distance between the ceiling face of the second cavity part 705 and the upper face of the window member 706 is set higher for the one at the step 1211 compared with the one at the step 1209. When completion of etching of the metal gate material 807 is detected by an end-point detection device or a film thickness measurement device, both of which are not shown, the plasma is extinguished and supply of the bias power and supply of the process gas are stopped to terminate etching processing. After that, adhesion force due to static electricity is removed and the wafer 708 is lifted up from the mounting surface on the wafer stage 709 and transferred out from the processing chamber 722 (the step 1212).

Incidentally, although omitted here, before or after the etching processings of the steps 1203, 1205, 1207, 1209, and 1211, similar to in the embodiment shown in FIG. 9, on/off of the electric field of the microwave, the magnetic field from the solenoid coil 704, and the bias potential by power from the RF power supply 710, and introduction and exhaust of process gas are performed.

According to the above modified embodiment, in etching processing of the multi-layered film structure shown in FIG. 12 using the plasma processing apparatus according to the embodiment of FIG. 7, by progressing etching processing by setting an optimal cavity height distribution depending on differences in the gas systems and the processing pressure, uniformity of characteristics of plasma such as the density or intensity can be improved in an in-plane direction of the wafer 708 and reproducibility and accuracy of processing can be improved.

According to the plasma processing apparatus and the plasma processing method shown in the embodiments described above, non-uniformity of plasma characteristics of plasma density can be reduced by adjusting individual cavity heights even when discharge conditions such as processing pressure are changed. In this way, processing results with improved uniformity in a plane direction of the sample can be obtained.

It should be further understood by those skilled in the art that although the foregoing description has been made on embodiments of the invention, the invention is not limited thereto and various changes and modifications may be made without departing from the spirit of the invention and the scope of the appended claims.

1. A plasma processing apparatus comprising:
a vacuum container;
a processing chamber which is arranged inside the vacuum container and inside which plasma is formed;
a sample stage which is arranged inside the processing chamber and on an upper face of which a sample is mounted;
a circular-shape plate member made of a dielectric material which is arranged above the processing chamber and through which an electric field supplied to form the plasma is transmitted;
a cavity part having a cylindrical shape which is arranged above the plate member and inside which a whole electric field is introduced;
a cylindrical-shape conduit an inside of which is coupled to a center of an upper part of the cavity and extends vertically through which the electric field is propagated; and
a generator arranged at an end part of the conduit for generating the electric field; wherein the cavity part comprises:
a first cylindrical cavity part having a cylindrical shape cavity with a large diameter and having the plate member as a bottom face;
a second cylindrical cavity part arranged above to be connected to the first cylindrical cavity part and having a cylindrical shape cavity with a small diameter; and
a step portion for connecting these between the first and the second cylindrical cavity parts.

2. The plasma processing apparatus according to claim 1, further comprising another step portion which connects the second cylindrical cavity part and the conduit therebetween wherein a ceiling face of the cavity part comprises a plane parallel to the plate member.

3. The plasma processing apparatus according to claim 1, wherein a ceiling face of the second cylindrical cavity part is arranged in parallel to the plate member, and wherein a height H2 of the ceiling face from an upper face of the plate member is set in a range of λ<H2<5λ/4 with respect to a wavelength)t. of the electric field.

4. The plasma processing apparatus according to claim 1,
wherein a ceiling face of the first cylindrical cavity part is arranged in parallel to the plate member, and
wherein a height H1 of the ceiling face from an upper face of the plate member is set in a range of λ/4<H1 with respect to a wavelength λ of the electric field.

5. The plasma processing apparatus according to claim 1, wherein a radius R2 of a cylindrical shape of the second cylindrical cavity part is set in a range of λ/4<R2 with respect to a wavelength λ of the electric field.

6. The plasma processing apparatus according to claim 1,
wherein the second cylindrical cavity part is arranged so that a center thereof matches to a center axis of the sample stage having a cylindrical shape, and
wherein the step portion is arranged more toward a center side than an outer circumference of the sample stage having a cylindrical shape with regard to a direction from the center axis toward an outer circumference.

7. The plasma processing apparatus according to claim 1,
wherein the electric field is an electric field of a microwave of 2.45 GHz, further comprising a magnetic field generation device for supplying a magnetic field of 875 Gauss inside the processing chamber to form the plasma by ECR inside the processing chamber.

8. The plasma processing apparatus according to claim 7, wherein the microwave of a TE11 mode is supplied from the conduit to the cavity part.
